(19) United States
(12) Patent Application Publication
(10) Pub. No.: US 2015/0096496 A1
(43) Pub. Date: Apr. 9, 2015

(54) VAPOR PHASE FILM DEPOSITION APPARATUS

(71) Applicant: HERMES-EPITEK CORPORATION, Taipei City (TW)

(72) Inventors: Noboru SUDA, Kyoto (JP); Takahiro OISHI, Sagamihara-shi (JP); Junji KOMENO, Fujisawa (JP); Po-Ching LU, Taipei City (TW); Shih-Yung SHIEH, Hsinchu City (TW); Bu-Chin CHUNG, Taipei City (TW)

(73) Assignee: HERMES-EPITEK CORPORATION, Taipei City (TW)

(21) Appl. No.: 14/502,801

(22) Filed: Sep. 30, 2014

(30) Foreign Application Priority Data
Oct. 4, 2013 (JP) 2013-209507

(51) Int. Cl. C23C 16/455; C23C 16/458

(52) U.S. Cl. CPC C23C 16/45508; C23C 16/4584; C23C 16/45563
USPC 118/730

(57) ABSTRACT

A film-deposition apparatus simultaneously realizes high partial pressure of volatile components, great flow velocity and smooth deposition rate curve at lower gas consumption. The apparatus comprises a disk-like susceptor, a face member opposing the susceptor, an injector, a material gas introduction portion, and a gas exhaust portion. A wafer holder retains a substrate, and a supporting member of the susceptor retains the wafer holder. The susceptor revolves around its central axis and the substrate rotates by itself. The opposing face member is structured so that a fan-shaped recessed portion and a fan-shaped raised portion are formed alternately in a radial manner, by which the height of the flow channel changes in a circumferential direction. The apparatus provides film deposition equivalent to that attained under optimal conditions by a conventional apparatus at a smaller flow rate of the carrier gas, and increases a partial pressure of material gases of volatile components.

### BACKGROUND OF THE INVENTION

1. Field of the Invention

The present invention relates to a vapor phase film deposition apparatus which forms a semiconductor film on a semiconductor or an oxide substrate and, in particular, relates to a rotation/revolution type vapor phase film-deposition apparatus which allows a substrate to rotate by itself or revolve around during film deposition.

2. Description of the Related Art

In general, it is considered that three factors are needed in keeping the high quality of film which is formed by a vapor phase film-deposition method. More specifically, they are a) film deposition pressure, b) flow velocity and c) curve of deposition rate. Hereinafter, a detailed description will be given regarding the influences of these factors on the quality of film.

First, a) film deposition pressure is important in particular where a highly volatile component is contained in elements of film. A system where significant volatilization from the film occurs is subjected to such treatment in which a film deposition pressure is elevated to increase a partial pressure of the volatile component, thereby suppressing dissociation of the volatile component from the film to provide a film with fewer defects and higher quality. For example, in the case of III-V compound semiconductors, due to high volatility of an group V element of the Periodic Table, it is necessary to increase a partial pressure of the group V element in vapor phase in order to suppress dissociation of the volatile component from the film. Among other things, in a nitride system-based compound semiconductor, it is often preferred to carry out film deposition at a pressure close to a normal pressure due to high volatility of nitrogen.

Next, with regard to b) flow velocity, the higher flow velocity is more desirable. Under normal film deposition conditions, a Reynolds number is not high enough to allow occurrence of turbulence. A higher flow velocity is preferable, if no turbulence occurs. A first reason thereof is that where the flow velocity is low, the interface of a film is deteriorated in quality. On general film deposition, various types of interface are formed on a film by changing compositions of the film or changing a doping material in the course of film deposition. Where the flow velocity is low, a material gas used in a film deposition layer prior to formation of interfaces is not fast exhausted. Thus, it is difficult to obtain a steep interface, resulting in a failure of keeping the interface in high quality. Another reason is that it takes a longer time from introduction of a source gas into a reactor to arrive at a substrate, by which precursors (raw material elements) are consumed at a higher percentage by vapor reactions. Thereby, the utilization efficiency of raw material is decreased. Still another reason is that where the flow velocity is low, it is difficult to control a random diffusion of raw material molecules by the flow velocity of gas, resulting in production of undesirable deposition at unintended parts (other than the substrate) inside the reactor, which may adversely influence the quality of film and reproducibility.

In a range at which no turbulence will occur, a higher flow velocity enables to stably realize a higher quality of film and a higher quality of interface. When consideration is given to the flow velocity in association with the film deposition pressure at the same flow rate of the carrier gas, a higher film deposition pressure is advantageous in suppressing dissociation of volatile components but can be disadvantageous in terms of flow velocity, because the flow velocity becomes slower with an increase in pressure, causing the film in lower quality. These two factors are basically not compatible. It is, therefore, necessary to conduct such operation that searches an optimal film deposition pressure and flow velocity from a comprehensive point of view.

Finally, consideration is given to c) the curve of deposition rate. FIG. 10 is a cross sectional view which shows a general rotation/revolution type reactor structure. More accurately, this is an example of reactor which is often used in film deposition of III-V group compound semiconductors. A reactor 100 is constituted with a disk-like susceptor 20, an opposing face member 110 which opposes the susceptor 20, a material gas introduction portion 60 and a gas exhaust portion 38. A substrate W is retained by a wafer holder 22, and the wafer holder 22 is retained by a supporting member 26 of the susceptor 20. The reactor 100 is centrosymmetric and structured so that the susceptor 20 revolves around its central axis and the substrate W rotates by itself at the same time. A mechanism for revolution and rotation as described above is publicly known. Further, the structure shown in FIG. 10 is also provided with a separately supplying type gas injector 120. The separately supplying-type gas injector 120 shown in FIG. 10 is divided by a first injector member 122 and a second injector member 124 into a gas introduction portion made up of three layers, i.e. upper, middle and lower layers. And this gas injector is often used in such a manner that a source gas of a H2/N2/group V element is introduced from the upper layer, a source gas of a group III element is introduced from the middle layer and H2/N2/group V is introduced from the lower layer. In the present invention, a curve obtained by plotting a deposition rate at every position on the susceptor 20 and the substrate W in a radial direction of the rotation/revolution type reactor 10 is defined as a curve of deposition rate.

FIG. 11 shows an ordinary curve of deposition rate obtained by the above-mentioned film deposition apparatus. This curve is dominated mainly by transport of raw material molecules. For example, in the case of III-V compound semiconductors, in most cases, film deposition is carried out, with a group V element being excessively supplied. Thus, only a group III element is handled as raw material molecules which dominate the deposition rate curve. A horizontal axis represents a distance from an injector end, whereas a longitudinal axis represents a deposition rate. A site at which deposition starts is substantially equal to an injector end where a source gas is introduced into a reactor from the separately supplying type injector. The deposition rate will increase from the site and soon decrease monotonously after the arrival at a peak. Regarding the position of the substrate, an uppermost upstream part of the substrate is usually arranged at a position slightly downstream from the peak of the curve of deposition rate. Next, the substrate is allowed to rotate by itself, by which a difference in deposition rate between upstream and downstream is eliminated to realize a relatively favorable uniformity of film thickness. In other words, the curve of deposition rate determines the uniformity of film thickness after rotation and revolution. In addition to the film thickness, chemical compositions of film, concentrations of dopants and others are greatly influenced by the deposition rate. Thus, the curve of deposition rate is quite important in terms of these characteristics and in-plane uniformity of the substrate. Therefore, the curve of deposition rate is regarded as one of the important factors which greatly influences the quality of film.

A deeper consideration will be given to the curve of deposition rate. This time, consideration will be given to important factors which influence the distribution of deposition rate. In a method for rotation/revolution type film deposition, film deposition is carried out quite often in a so-called mass transport rate-determining mode in which mass transport mainly based on diffusion of raw material molecules determines the deposition rate under the flow field in a laminar flow mode. In this case, (1) the concentrations of raw material molecules in a gas, (2) the flow rate of carrier gas and (3) the height of flow channel are regarded as major factors which influence the distribution of deposition rate. In addition, in the present invention, a description of flow rate of carrier gas is used as a term which covers a total flow rate of all types of gases used in film deposition, in addition to simply as a carrier gas. Among the above-described factors of (1) to (3), regarding (1) the concentrations of raw material molecules, there is a simple relationship that the deposition rate is proportional to the concentrations of raw material molecules (refer to FIG. 12 which shows the conversion of the curve of deposition rate when the concentrations of raw material molecules are changed).

Next, in giving consideration to (2) flow rate of the carrier gas, in FIG. 13, a difference in the curve of deposition rate is shown when the flow rate of the carrier gas is changed. In addition, when the flow rate of the carrier gas is changed, all the other film deposition conditions are to be kept unchanged. In this drawing, if a) is taken as a curve of deposition rate when a certain flow rate of the carrier gas is given as F0, each of b) and c) shows a curve of deposition rate at a flow rate of the carrier gas which is respectively twice or triple higher than a). The above description appears, with an increase in carrier gas, the curve of deposition rate changes so as to shrink in a longitudinal direction and extend in a lateral direction. Quantitatively, when the flow rate is multiplied a times, the curve of deposition rate is substantially consistent so as to be multiplied by 1/a longitudinally and multiplied by square root α (√α) laterally. This is due to the fact that in the previously described laminar flow mode and also the mass transport limited mode, the deposition rate is proportional to an gradient of concentrations of raw material molecules in a direction perpendicular to a face of a substrate or of the susceptor and the distribution of concentrations of raw material molecules in a flow channel is substantially in accordance with a solution of the advective diffusion equation under a boundary condition that the concentrations of raw material molecules on the surface of the substrate or the susceptor are zero. Next, a relationship between the above-described flow rate of carrier gas and the curve of deposition rate is derived by the similar rule of the advective diffusion equation.

Further, a description will be given for the influences of (3) the height of flow channel on the curve of deposition rate. FIG. 14 shows the curves of deposition rate when the height of the flow channel is changed. When a) is taken as a curve of deposition rate given at a certain height of the flow channel of L0, each of b) and c) shows a curve of deposition rate at the height of the flow channel which is respectively twice or triple higher than the height of a). This is also subjected to the similar rule of the advective diffusion equation as the flow rate. When the height of the flow channel is multiplied by α, the curve of deposition rate is substantially consistent so as to be multiplied by 1/α longitudinally and multiplied by square root α (√α) laterally.

With regard to the above description of (1) to (3) factors, consideration will be summarized as follows. With an increase in (2) the flow rate of carrier gas and also with an increase in (3) the height of flow channel, the curve of deposition rate is accordingly distributed in the shape that extends relatively in a radial direction, that is, in the shape that is relatively low inclination. Finally, an absolute value of the deposition rate is determined by (1) the concentrations of raw material molecules.

In addition to the three factors of (1) to (3), hereinafter, consideration will be given for the influences of the film deposition pressure on the curve of deposition rate. According to the advective diffusion equation, where a ratio of flow velocity to diffusion coefficient is constant, the distribution of concentrations of raw material molecules in a flow channel is kept unchanged. When consideration is given to a case where only a pressure is changed at the same flow rate of the carrier gas, the flow velocity is inversely proportional to the pressure and the diffusion coefficient is also generally inversely proportional to the pressure. As a result, a ratio of the flow velocity to the diffusion coefficient is kept unchanged. Thus, when only the pressure is changed, substantially similar results are to be obtained. However, where chemical reactions in vapor phase cannot be disregarded, the chemical reactions proceed differently due to the flow velocity and pressure, which can lead to different results.

Since roles of the three factors which dominate the curve of deposition rate are made apparent, from now on, consideration will be given to an ideal curve of deposition rate. As described previously, the three factors are changed to obtain a variety of curves of deposition rate, and these curves have their own advantages and disadvantages. In a relatively steep curve of deposition rate obtained when a carrier gas flow rate is lower or when the height of the flow channel is lower, most of the raw material molecules contained in a source gas will be exhausted until the source gas is discharged. Therefore, there is such an advantage that the utilization efficiency of raw material is high. On the other hand, there is such a disadvantage that a thicker deposition layer is inevitably formed on the susceptor upstream from the substrate. This upstream deposit may not only deteriorate the quality of film but also may contribute to unstable film deposition, thus resulting in a decrease in yield or an increase in maintenance frequency that lead to high costs. Further, there is a great difference in deposition rate between upstream and downstream. Therefore, it is more likely to make a difference in quality of film such as compositions or concentrations of dopants between the center of the substrate where film deposition is carried out always at the same deposition rate and a peripheral part of the substrate where film deposition is carried out alternately at slow and fast deposition rates, thus reducing the uniformity of film.

When the flow rate of the carrier gas is greater or when the height of the flow channel is higher, conversely the distribution of deposition rate is smoother. In this case, although the utilization efficiency of raw material is relatively low, the adverse influences due to the upstream deposit will be reduced and the quality of film will become more uniform. As described above, there are advantages and disadvantages in any case. Thus, a comprehensive judgment is made to select an optimal curve of deposition rate in view of the points such as the quality of film and productivity. However, when only the quality of film or uniformity of film is taken into account, a smooth curve of deposition rate is more desirable.

Here, reverting to the three factors described at the beginning of the specification, that is, a) film deposition pressure (in particular, a partial pressure of volatile components), b) flow velocity and c) curve of deposition rate, influences of these factors on the quality of film will be summarized. In order to obtain a good quality of film or uniformity of film, the higher a) the film deposition pressure becomes, the better the result will be; the higher b) the flow velocity becomes, the better the result will be; and the lower c) the curve of deposition rate becomes, the better the result will be.

Now, in order to obtain a high flow velocity at a high film deposition pressure, with a flow rate of the carrier gas being fixed, the only way is to decrease the height of the flow channel. However, a decrease in height of the flow channel will make c) the distribution of deposition rate become steep, which is not desirable for the quality of film. On the other hand, in order to realize a smooth distribution of deposition rate in the above-described condition, the only way is to increase the flow rate of the carrier gas. However, an increase in only the flow rate of the carrier gas will decrease a percentage of material gases of volatile components, thereby resulting in a decreased partial pressure of the volatile components, which is not desirable. Finally, it is necessary to increase the material gas of the volatile components, along with the carrier gas. Since the material gas is expensive, it is in reality impossible to increase the material gas without any limitation.

To the contrary, under a reduced pressure which realizes a high flow velocity, basically the only way is to decrease partial pressures of every gas. However, an increase in percentage of the material gas of volatile components in a carrier gas is able to realize a high partial pressure even under a reduced pressure. Hereinafter, consideration will be given to this possibility. As described previously, a supply flow rate of the material gas cannot be increased without any limitation but with a superior limitation. As a result, in order that the material gas is increased in partial pressure at a certain pressure and also at a predetermined material gas flow rate, it is necessary to decrease a carrier gas other than the material gas. In order to obtain a smooth curve of deposition rate at a smaller flow rate of the carrier gas, the height of the flow channel may be increased. However, when the height of the flow channel is increased at a smaller flow rate of the carrier gas, the flow velocity is synergistically decreased. Thus, the quality of film and productivity are significantly decreased even under a reduced pressure.

### SUMMARY OF THE INVENTION

From the above consideration, it is difficult to satisfy the three factors at the same time, that is, a high partial pressure of volatile components, a high flow velocity and a smooth distribution of deposition rate, with a flow rate of material gas kept at a realistic level, by using a conventional apparatus. It is almost impossible to satisfy these factors in particular in a large-sized apparatus for mass production.

In view of the above-described problems with conventional technology, an object of the present invention is to provide a film deposition apparatus which is capable of realizing the three factors at the same time, that is, a high partial pressure of volatile components, a high flow velocity and a smooth curve of deposition rate, with lower gas consumption.

The present invention is directed to a vapor phase film deposition apparatus having a disk-like susceptor which has a wafer holder for holding substrates for film deposition, a mechanism which allows the substrates to rotate by itself and revolve around, an opposing face which opposes a wafer holder to form flow channels, an introduction portion and a exhaust portion of a material gas of each flow channel in which recessed and raised profiles are formed on the opposing face so that a distance between the disk-like susceptor and the opposing face is changed in a direction at which the substrate revolves around.

In one of the major aspect, a disk-like injector is provided at an introduction portion of the material gas and recessed and raised profiles are formed on the injector so as to correspond to the recessed and raised profiles formed on the opposing face. In another aspect, a method for film deposition is based on chemical vapor growth. Still another mode is such that a film to be formed is a compound semiconductor.

Further, in another aspect, a part of the material gas contains an organic metal. In still another aspect, a member which constitutes the opposing face and the injector is made of any one of metal material, such as stainless steel, molybdenum; carbide, such as carbon, silicon carbide and tantalum carbide; nitride such as boron nitride and aluminum nitride, and oxide-based ceramic such as quartz and alumina or in combination thereof. The above-described object and other objects of the present invention as well as characteristics and advantages will be made apparent from a detailed description given hereinafter and attached drawings.

According to the present invention, it is possible to realize film deposition equivalent to that obtained by using a conventional apparatus under optimal conditions at a smaller flow rate of the carrier gas. It is also possible to dramatically increase a partial pressure of material gases of volatile components as compared with a conventional case and, as a result, to form a film with higher quality than a conventional film.

### BRIEF DESCRIPTION OF THE DRAWINGS

FIG. 1 is a plan view which shows an opposing face member of the present invention.

FIG. 2 is a cross sectional view taken along the line of A-A in FIG. 1.

FIG. 3 is a plan view which shows another example of the opposing face member.

FIG. 4 is a cross sectional view which shows another example of the opposing face member.

FIG. 5 is an exploded perspective view which shows a reactor structure of the present invention.

FIG. 6 is a cross sectional view which shows the reactor structure of the present invention.

FIG. 7 is an exploded perspective view which shows an injector structure of the present invention.

FIG. 8 is a drawing which shows a curve of deposition rate obtained in an experimental example of the present invention.

FIG. 9 is a drawing which shows photoluminescence spectrum of a multiple quantum well obtained in the experimental example of the present invention.

FIG. 10 is a cross sectional view which shows a reactor structure of a conventional rotation/revolution type film deposition apparatus.

FIG. 11 is a drawing which shows a common curve of deposition rate and arrangement of a substrate which rotates by itself and also revolves around.

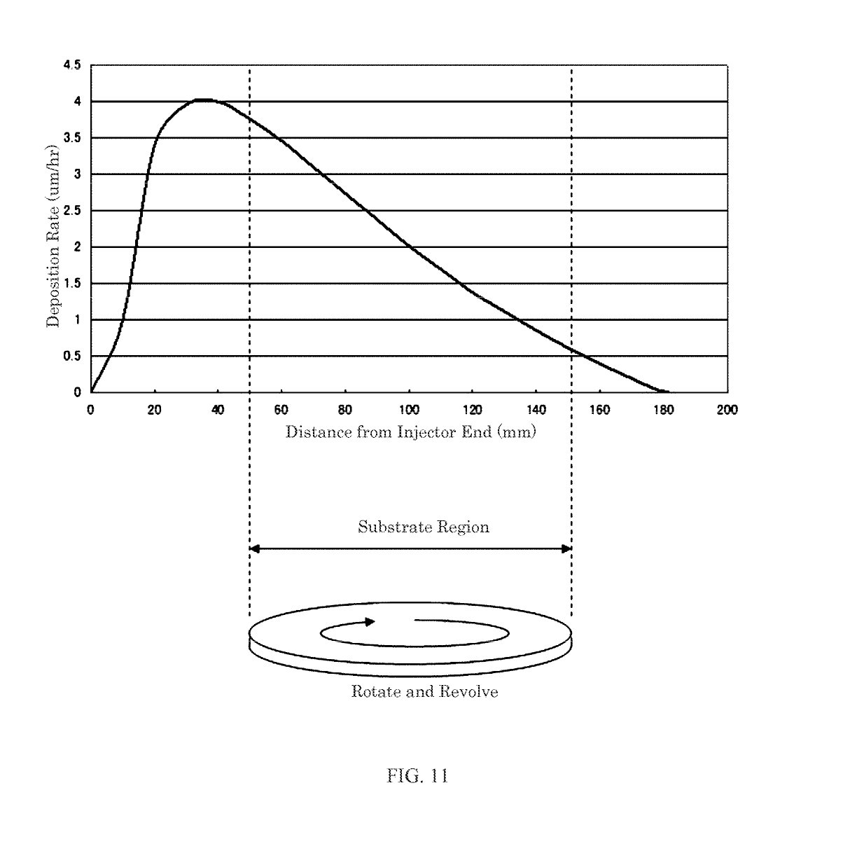

FIG. 12 is a drawing which shows a change in curve of deposition rate when concentrations of raw material molecules are changed.

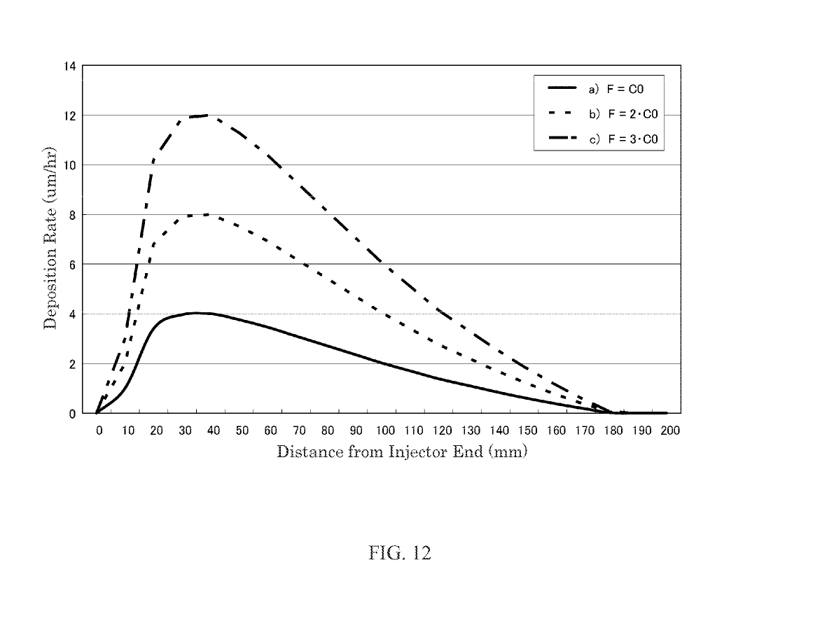

FIG. 13 is a drawing which shows a change in curve of deposition rate when a flow rate of the carrier gas is changed.

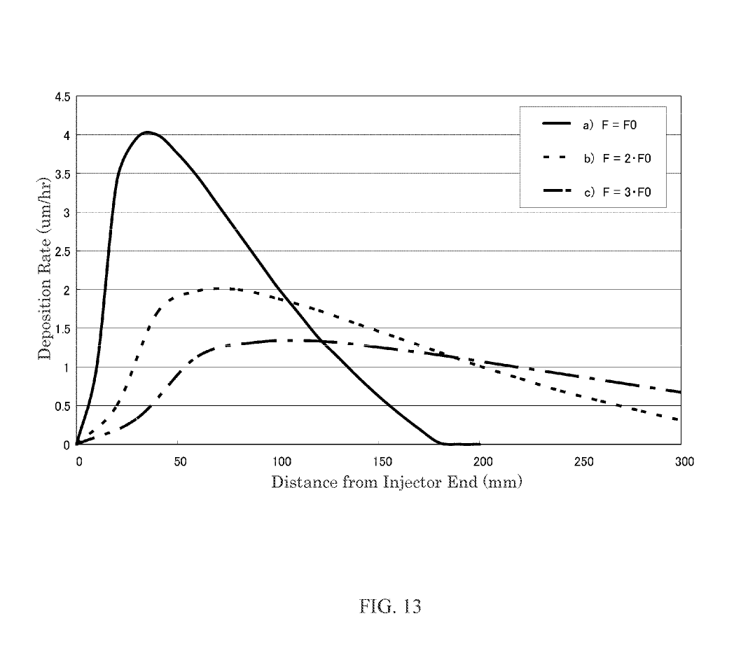

FIG. 14 is a drawing which shows a change in curve of deposition rate when height of the flow channel is changed.

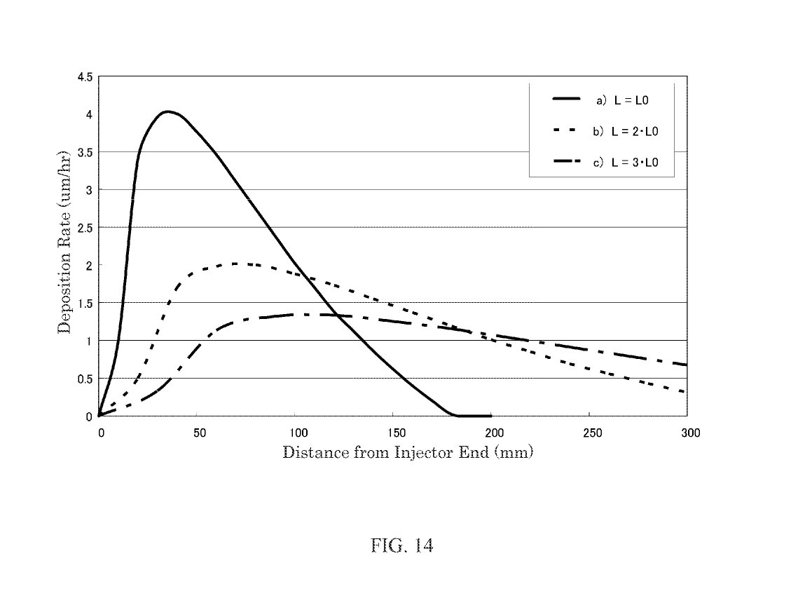

### DETAILED DESCRIPTION OF THE PREFERRED EMBODIMENTS

Hereinafter, a detailed description will be given of the best mode for carrying out the present invention on the basis of examples.

### Example 1

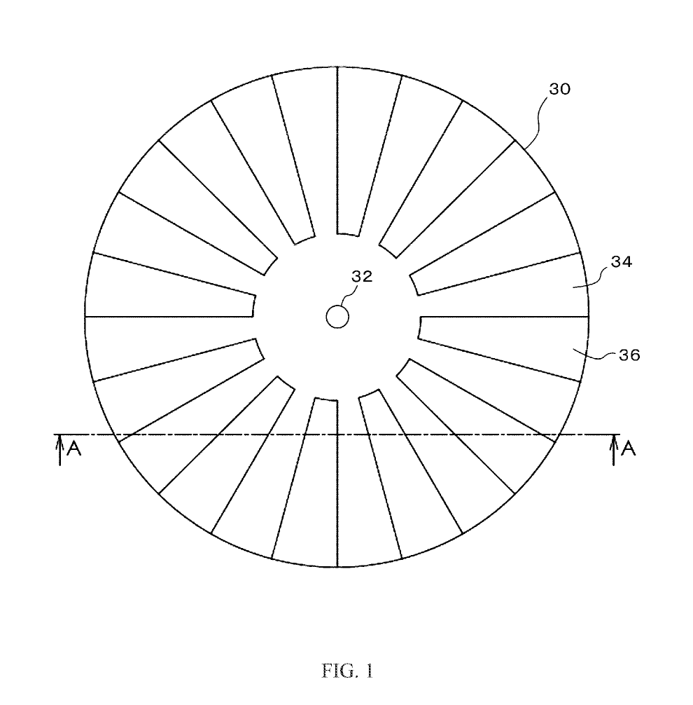

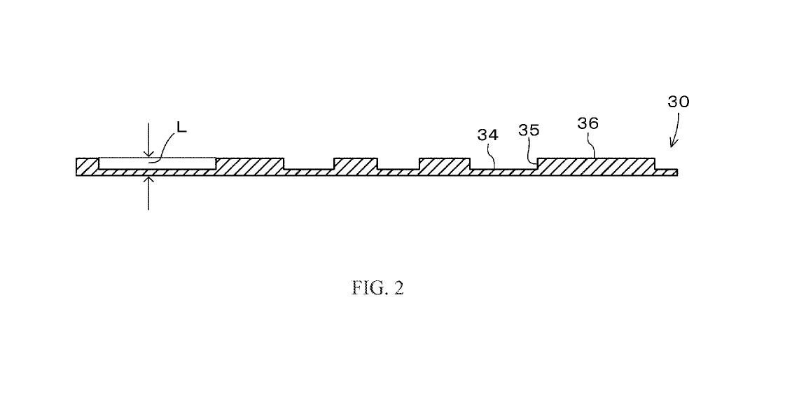

First, a description will be given of a concept of the present invention with reference to FIG. 1 and FIG. 2. The inventors have diligently studied to solve the above-described problems, they found a reactor structure that is able to realize a sufficient flow velocity at a lower consumption of carrier gas and also able to realize an optimal curve of deposition rate. A method thereof is to provide recessed and raised profiles on an opposing face to form flow channels which spread radially from the center of a reactor and which are separated from each other, thereby limiting the area contributing to film deposition to the flow channels. In conventional technologies, there have been a method in which an opposing face is formed in the shape of a cone and a method in which a step is disposed on its way to a flow channel (for example, Japanese Published Unexamined Patent Application No. 2005-5693 or the like). However, in both of these methods, the flow channels are constant in height when viewed from the circumference. Therefore, according to the technology disclosed in Japanese Published Unexamined Patent Application No. 2005-5693, it is an advantage that undesirable deposition at a region upstream from the substrate can be decreased. However, since the flow channels are constant in height at a substrate region in a circumferential direction, a curve of deposition rate at the substrate region is essentially not different from that obtained in a normal flow channel. Therefore, the structure is not free of the previously described problems, i.e. the three factors of the film deposition pressure, the flow velocity and the curve of deposition rate are associated with each other. In the present invention, the flow channels are changed in height in the circumferential direction. And, in this sense, the present invention is a completely different mode from a conventional apparatus and provided with the efficacy stated below.

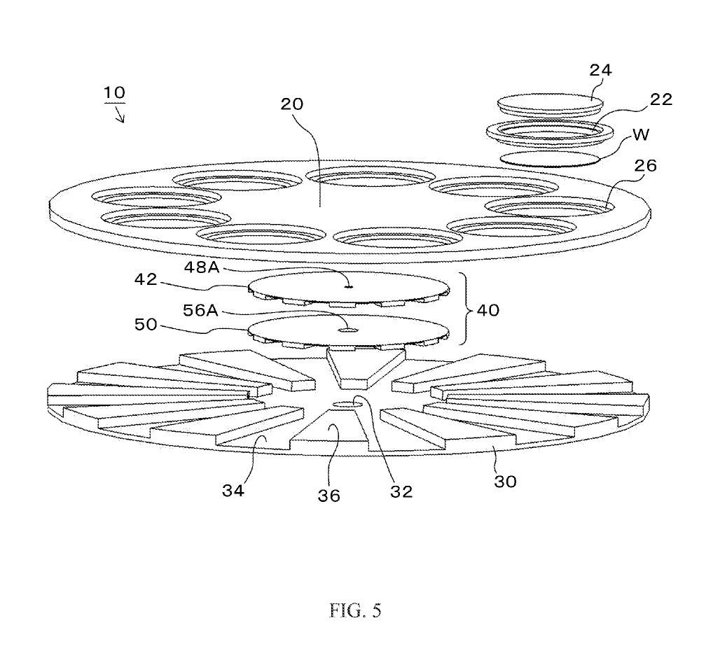

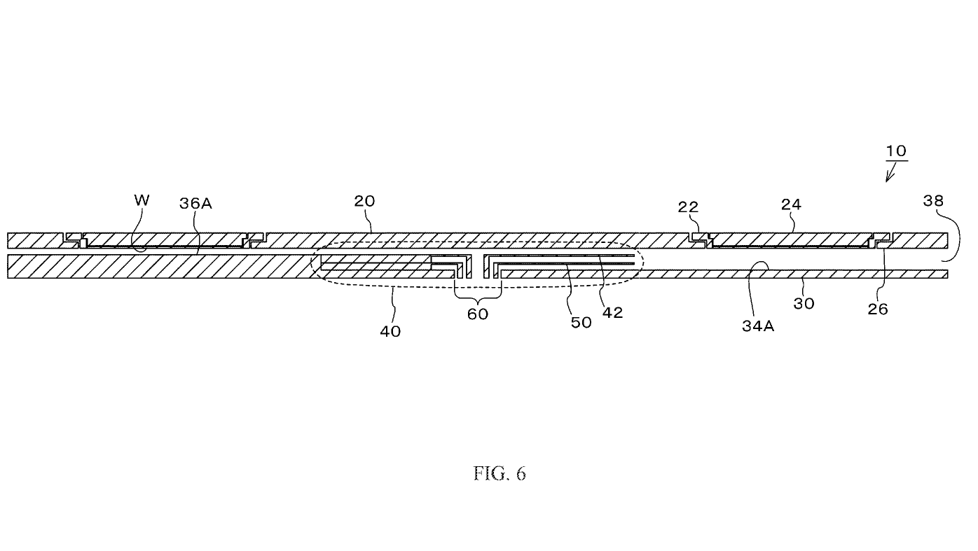

A concept of the present invention is shown in FIG. 1 and FIG. 2. FIG. 1 is a plan view of an opposing face member which constitutes a film deposition apparatus of the present invention. FIG. 2 is a cross sectional view taken along the line of A-A in FIG. 1. A reactor structure of the film deposition apparatus is illustrated in FIG. 5 and FIG. 6. Here, for the sake of describing a basic concept of the present invention, description will be given of only an opposing face member 30. In addition, a reactor structure 10 itself is fundamentally similar to the reactor structure 100 of the above-described Background Art. The present invention has features with regard to the profile of the opposing face member 30 which is opposed to a susceptor 20. The opposing face member 30 is provided with an opening 32 at the center from which a recessed portion 34 and a raised portion 36 are radially formed in alternative manner. The opposing face to the susceptor 20 is formed as described above, by which a source gas hardly flows into the raised portion 36 and the most gas flows into the recessed portion 34. Therefore, film deposition is carried out fundamentally only at the recessed portion 34.

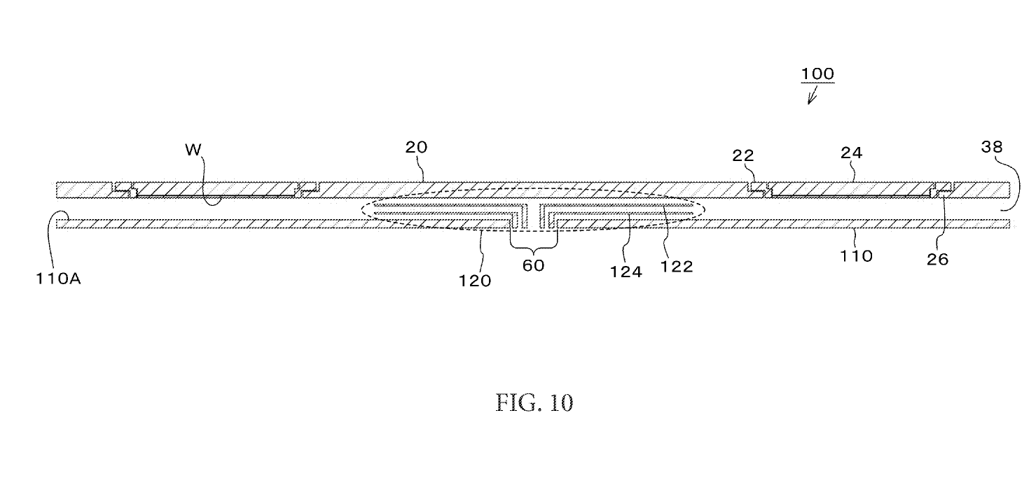

A description will be given of a concept of the present invention with reference to another example. Now, in a conventional structure (refer to FIG. 10), optimal film deposition conditions are assumed to be attained from the height of the flow channel L0 in terms of a film deposition pressure, a flow velocity and a curve of deposition rate. The structure of the present invention is set so that an area ratio of the raised portion 36 to the recessed portion 34 is 1:1 and the height of the flow channel L at the channel portion 34 (refer to FIG. 2) is the same as an optimal value L0 of the conventional structure. For the purpose of facilitating the understanding, it is assumed that no gas flows into the raised portion 36 and the gas only flows into the recessed portion 34. In an actual structure, it is impossible to completely limit a film deposition area to the recessed portion 34. However, since it is possible to easily realize a situation closer to the above, consideration may be given under the above assumption. The film deposition pressure can be controlled arbitrarily and, therefore, is set under the same conditions as those of the conventional structure.

In order that the above described structure of the reactor is used to attain a favorable curve of deposition rate similar to a conventional curve of deposition rate, a flow velocity of the flow channel at a recessed portion may be made consistent with a conventional flow velocity. The structure of the present invention is half in a cross sectional area through which a gas flows as compared with the conventional structure. Thus, half a flow rate of the carrier gas suffices to obtain the same flow velocity. In other words, under the above-described condition, the height L0 of the flow channel and the flow velocity at the recessed portion 34 are also completely equivalent to the conventional optimal conditions, thus, always enabling to obtain an optimal curve of deposition rate.

Next, consideration will be given to an absolute value of the deposition rate. In the structure of the present invention, a region contributing to film deposition is reduced to half as compared with the conventional structure, which has the effect of reducing an absolute value of the deposition rate to half. On the other hand, since a carrier gas is reduced to half, the concentration of raw materials in the gas are increased twice, which has the effect of increasing the deposition rate twice. As a result, these effects counterbalance each other, by which an absolute value of the deposition rate is made equivalent to a conventional absolute value. That is, raw material molecules are fed in the same quantity to obtain a deposition rate similar to a conventional deposition rate, but the utilization efficiency of raw materials will not be decreased.

From the description given so far, it is apparent that adoption of the structure of the present invention enables to realize a state which is identical with a conventional optimal condition at half a quantity of a carrier gas used by the conventional structure. Only this fact is able to reduce a quantity of the used carrier gas and also greatly advantageous in reducing the production cost. In fact, the present invention has another important advantage. In decreasing a flow rate of the carrier gas, the flow rate of material gases of volatile components is kept the same as a conventional flow rate, by which a percentage of material gases of volatile components in the carrier gas will increase accordingly. Therefore, it is possible to greatly increase a partial pressure of material gases of the volatile components as compared with a conventional case. In this case, a further description will be given by referring to III-V group semiconductors. With regard to film deposition conditions of the present invention, a ratio of a group V element to a group III element as one of the most important parameters of film deposition is set the same as a conventional ratio. Since the group III element may be supplied in the same quantity as a conventional quantity, a material gas of the group V element may be also supplied in the same quantity. On the other hand, since the flow rate of the carrier gas is reduced to half as compared with a conventional flow rate, a percentage of the material gas of group V element in a flow rate of all supplied gases is increased twice. As a result, a partial pressure of the material gas of the group V element is also increased twice. This high partial pressure is effective in suppressing dissociation of atoms of the group V element from a film, thus making it possible to obtain a film in higher quality than a conventional film.

As described so far, according to the method of the present invention, it is possible to realize film deposition which is equivalent to that realized under optimal conditions by a conventional apparatus at a smaller flow rate of the carrier gas. It is also possible to dramatically increase a partial pressure of material gases of volatile components as compared with a conventional case and, therefore, possible to form a film in higher quality than a conventional film.

As described previously, in the actual structure, the film deposition area cannot be exclusively limited to the recessed portion 34. A height ratio of the raised portion 36 to the recessed portion 34 and an area ratio thereof are appropriately selected, thus making it possible to obtain effects of the present invention sufficiently. Further, a side wall 35 of the flow channel which is a side face of the raised portion slightly influences a flow pattern, the influence of which is, however, limited. If the influence of the side wall 35 is desired to be corrected, the correction can be made by slightly adjusting gas conditions, because the correction relates to a flow velocity.

Finally, consideration will be given to temporal transition of the deposition rate. In the present invention, during revolution of the substrate, gas passes alternately through a film deposition region which is the recessed portion 34 and a region free of film deposition which is the raised portion 36. Therefore, when temporal transition of the deposition rate is taken into account, the temporal transition is considered to be formed in a rectangular shape or in a pulse manner. Whether this poses a problem or not is, as a matter of course, a concern. In this connection, there has been recently reported a method for film deposition in which raw materials are supplied in a pulse manner such as pulse MOCVD (C. Bayram et, al. Proc. of SPIE Vol. 7222 722212-1 or others). This method provides results better than those obtained by a usual method for film deposition. With the above description taken into account, it may be safe in saying that no fundamental problem is posed in terms of temporal transition of the deposition rate in a rectangular shape or in a pulse manner. Further, with regard to influences of the deposition rate in a pulse manner on the uniformity of film, this deposition rate will not affect the uniformity, because the deposition rate in a pulse manner is similarly found everywhere on the substrate. That is, as with a conventional method, it may be safe in saying that the uniformity is dominated after all only by the curve of deposition rate. From the consideration given so far, it can be concluded that temporal transition of the deposition rate in a pulse manner will not be disadvantageous in every respect.

As described so far, the present invention is completely free of conventional disadvantages and at the same time is provided with a great advantage that the film is greatly improved in quality and gas consumption is greatly reduced due to a high partial pressure of material gas.

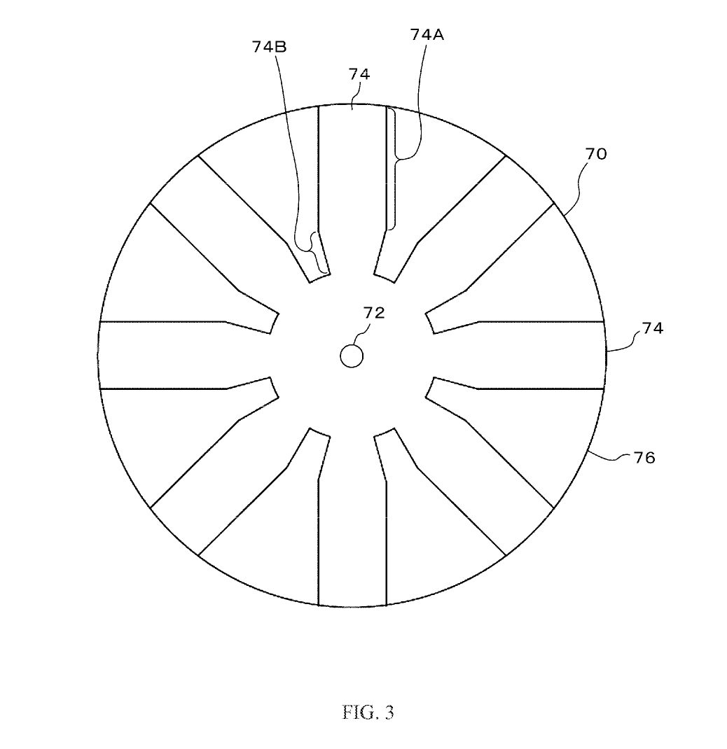

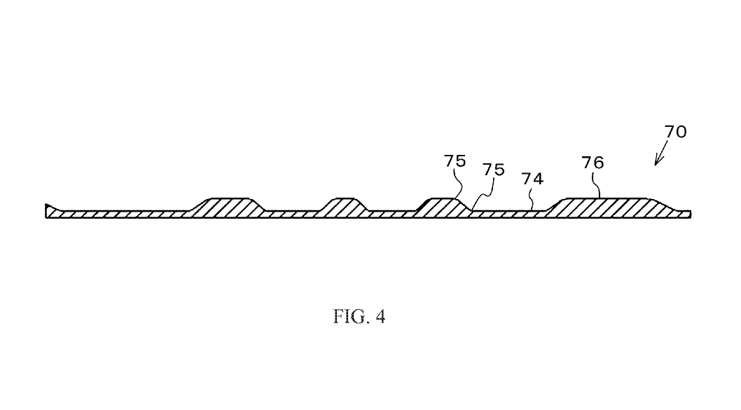

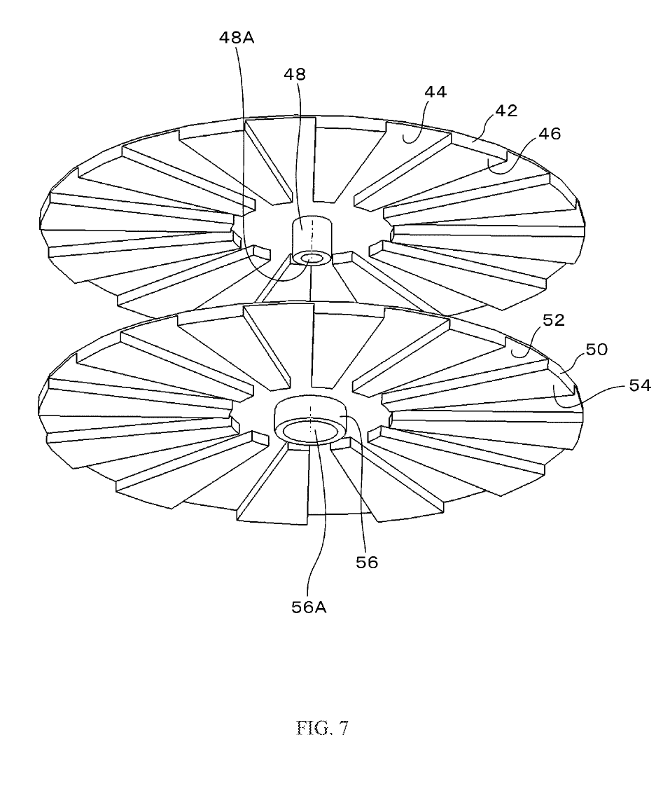

Next, a detailed description will be given of the structure of the film deposition apparatus of the present invention with reference to FIG. 3 to FIG. 7. FIG. 3 is a plan view which shows another example of the opposing face member. FIG. 4 is a cross sectional view which shows another example of the opposing face member. FIG. 5 is an exploded perspective view which shows a reactor structure of the present invention. FIG. 6 is a cross sectional view which shows the reactor structure of the present invention. FIG. 7 is an exploded perspective view which shows an injector structure of the present invention. As shown in FIG. 5 and FIG. 6, it is acceptable that the structure other than the opposing face member 30 and the injector 40 is identical with a conventional structure. Regarding the profile of the opposing face which is an essential part of the present invention, design parameters include a planar shape and a cross sectional profile of the opposing face, an area ratio and a height ratio of recessed portion to raised portion, and the number of divisions of flow channels.

FIG. 1 is a plan view which shows an example of the recessed portion 34 formed in a fan shape. Similar effects can be obtained in a rectangular shape or in combination thereof. It is acceptable that deposition conditions and others are taken into account to select an appropriate shape dependent on respective film deposition conditions. An opposing face member 70 shown in FIG. 3 illustrates a recessed portion 74 is formed in a profile that combines a rectangular portion 74A with a fan-shaped portion 74B. Further, FIG. 2 shows a cross sectional shape of the recessed portion which is rectangular as an example. Of course, it is apparent that a trapezoid, a triangle or a curved face such as sine curve can provide similar effects. In view of attaining a smoother flow field, a profile including a curved face may be preferred. FIG. 4 shows an example of the recessed and raised profiles, cross section of which is a trapezoid and in which a fillet 75 is provided at the edge.

Next, with regard to an area ratio of the recessed portion 34 to the raised portion 36, the smaller the area ratio of the recessed portion 34 is, the higher the effect of reducing the carrier gas and thus the effect of increasing a partial pressure of material gases of volatile components become. However, an excessively small area of the recessed portion 34 will result in longer passage time of the gas through the raised portion 36 which does not contribute to growth. This may be disadvantageous in forming a very thin layer depending on the case. Although relating to the rotation/revolution speeds, a permissible area ratio of the recessed portion 34 may be about 20% to 80%.

With regard to a height ratio of the recessed portion 34 to the raised portion 36, the susceptor rotates by itself and also revolves around, whereas the opposing face remains stationary, by which a clearance is required between the raised portion 36 and the susceptor 20. Of course, a higher ratio of the height of the flow channel at the recessed portion 34 to that at the raised portion 36 (distance between the susceptor and the opposing face) will accordingly provide greater effects of the invention. However, even a slight difference in height will exert some effects. If actually satisfactory effects are to be obtained, the height ratio of the raised portion to the recessed portion is desirably about 1:2. In order to increase the height ratio, the smaller the distance between the raised portion 36 and the susceptor 20 is, the greater the effect will become. However, an excessively small distance results in a higher risk that the susceptor 20 may be in contact with the raised portion 36 of the opposing face due to thermal deformation of the susceptor 20 or the others. Therefore, the clearance between the raised portion 36 and the susceptor 20 may be required to be at least about 1 mm. The height of the flow channel at the recessed portion 34 is required to be consistent with an optimal condition of a conventional type. The height of the flow channel actually used in a rotation/revolution type reactor varies from 5 mm to 40 mm. If the height of the recessed portion 34 is selected to be 40 mm, effects will be provided by even setting the height of the raised portion 36 to be about 20 mm. Further, if the height of the recessed portion is set to be 5 mm, the height of the raised portion 36 is decreased to be 2.5 mm or less, preferably about 1 mm. With the above description taken into account, it is desirable that the height of the raised portion 36 is selected to be 1 mm to 20 mm and the height of the recessed portion 34 is selected to be 5 mm to 40 mm depending on other conditions.

The last design parameter of the profile of the opposing face is the number of divisions of the flow channels. The larger the number of divisions is, the smaller the bias in a circumferential direction becomes. Thus, in light of this, the larger the number of divisions is, the better the result will be. However, when the number of divisions is increased to make excessively small the width of the flow channel at the recessed portion, the side wall 35 of the flow channel becomes more influential. Although this will not instantly pose a problem, there is inevitably found a great divergence from data obtained by a conventional method. With the above description taken into account, the number of divisions may be appropriately in a range of 3 to 30, which is, however, not very accurate. A large-size reactor used for mass production is able to utilize the data obtained by a conventional method, as it is, within this range, although depending on the size of the reactor. Where the number of divisions is smaller than 3, an area per raised portion is increased, resulting in an excessively long time of a gas passing through. Further, where the number is larger than 30, the width of the flow channel is excessively narrow, by which a side wall face of the flow channel exerts prominent influences on gas streams in view of fluid dynamics.

In addition to the profile of the opposing face, it is desirable to change the profile of the injector in accordance with recessed and raised profiles of the opposing face. In this case as well, a description will be given by referring to III-V compound semiconductors. The injector frequently used in this field has such functions that group V and III elements of the Periodic Table are mixed adjacent to the substrate as much as possible and, then, the injector is kept at a low temperature, thereby suppressing precursor reactions of raw material molecules. In a conventional apparatus, as shown in FIG. 10, an injector 120 is fundamentally constituted with a first injector member 122 and a second injector member 124, each of which is in a simple disk-like shape. On the other hand, in the present invention, for the purpose of preventing the occurrence of turbulence, as shown in FIG. 5 or FIG. 7, it is preferred that flows inside the injector are also divided so as to continue to flow channels on the opposing face.

More specifically, as shown in FIG. 5 and FIG. 7, in this example, a first injector member 42 and a second injector member 50 which constitute a separately supplying type injector 40 are a surface profile similar to that of an opposing face member shown in FIG. 3. The first injector member 42 is such that a fan-shaped recessed portion 44 and a fan-shaped raised portion 46 are radially formed in an alternative manner and provided at the center with a gas introduction port 48 in which a through hole 48A is formed. The second injector member 50 is configured that a fan-shaped recessed portion 52 and a fan-shaped raised portion 54 are radially formed in an alternative manner and provided at the center with a gas introduction port 56 in which a through hole 56A is formed.

The above-described structure is provided, by which an injector member is able to have a larger area which is in contact with a lower face. Next, the contact portion is used as a heat sink, thus making it possible to keep the injector at a lower temperature than a conventional apparatus. Technology in Japanese Published Unexamined Patent Application No. 2011-155046 discloses that an injector is brought into contact with a lower face and cooled. In the above-described invention, a contact portion thereof is formed in a cylindrical shape, thereby preventing occurrence of turbulence. However, the effect is not sufficient. The structure of the present invention is able to have a sufficiently great contact area and also prevent occurrence of turbulence and, therefore, definitely advantageous.

A description has been so far given of the structure which is provided with the injector 40. The present invention shall not be, however, limited to the use of an injector. Frequently, no injector is used on film deposition of arsenic-based or phosphorous-based compound semiconductors. It is apparent that a concept of the present invention in which recessed and raised portions are formed on an opposing face and divided into a plurality of flow channels can be used in this case as well and effects of the invention can be obtained.

Further, in the drawings used in the above description, there is shown a so-called face down type apparatus in which the surface of the substrate faces downward in a perpendicular direction. Under ordinary film deposition conditions, gravitational influences are slight. Thus, it is self-evident that the effects of the present invention can be obtained also in a so-called face up apparatus in which the surface of substrate faces upward. Therefore, the present invention shall not be limited to a face down type apparatus.

A material used to constitute the opposing face member 30 and the injector 40 of the present invention may basically include any material, as long as it is able to meet the degree of the purity as well as heat resistance and corrosion resistance to the ambient environment. More specifically, there are included metal material such as stainless steel, molybdenum; carbide such as carbon, silicon carbide and tantalum carbide; nitride such as boron nitride, silicon nitride and aluminum nitride, and oxide-based ceramic such as quartz and alumina which are generally used on film deposition of semiconductors or oxides. And, any material may be selected appropriately from them.

### Experimental Example 1

### Curve of Deposition Rate of Gallium Nitride Film

Next, an example will be introduced in which the present invention is applied to the deposition of a gallium nitride film, then compared with a conventional method. First, a description will be given of an example prepared by the conventional method for comparison. In the conventional example, a reactor has a cross-sectional structure shown in FIG. 10. The apparatus was used to set conditions in consideration of quality of film, utilization efficiency of raw materials, consumption of carrier gas and flow velocity, finding that an optimal film deposition pressure was 25 kPa, a height of the flow channel was 14 mm, and a flow rate of the carrier gas was 120 SLM. On the other hand, in the structure of the present invention, as an opposing face member, there was adopted an opposing face having a rectangular cross section as shown in FIG. 1 and FIG. 2 to give a flow channel divided into 12 portions. Each pair of the recessed portion 34 and the raised portion 36 had 15 degree angle therebetween and was provided with periodicity of 30 degrees. Therefore, each pair was formed in a symmetrical shape for 12 times. A distance between the recessed portion 34 and the susceptor 20 remains 14 mm, that is, an optimal value of the conventional structure, and a distance between the raised portion 36 and the susceptor 20 was 4 mm. Carbon was used as a material of the opposing face member.

Further, corresponding to the conventional structure, an injector is of a three-layer flow. A flow channel made up of three layers was 4 mm per layer in height, and each partition plate therebetween for dividing them was 1 mm in thickness, a total of 14 mm which was equivalent to the height of the flow channel at an opposing face portion. Regarding these three layers, each of the lower two flow channels was shaped to be divided into 12 portions so as to continue to a flow channel on the opposing face, while the upper layer was free of division and shaped to flow evenly at 360 degrees. In addition, the injector is made of molybdenum. The structure was shown in FIG. 5 and FIG. 6. FIG. 5 is a perspective view in which the structure was disassembled into components. FIG. 6 is a cross sectional view in which the structure was assembled. A right half part of the cross sectional view shows a flow channel of the recessed portion, while a left half part thereof shows a flow channel of the raised portion.

The Table 1 below showed the gas conditions on film deposition of the gallium nitride film. In the conventional example, the conditions for a total flow rate of the carrier gas being 120 SLM, in the examples of the present invention, given were experimental conditions, that is, a total flow rate of 120 SLM equivalent to that of the conventional example, 60 SLM; that is, half the above total flow rate; and 35 SLM at which a curve of deposition rate similar to that of the conventional example was consequently obtained.

TABLE 1

| | | | Carrier gas flow rate | | | Flow | Partial |
|---|---|---|---|---|---|---|---|
| | | Growth | (SLM) | | | rate of | pressure |
| | Structure of | pressure | | | Total | TMGa | of |
| | apparatus | (kPa) | H₂ | NH₃ | flow rate | (sccm) | NH₃ (kPa) |
| a) | Conventional | 25 | 96 | 24 | 120 | 100 | 5 |
| | type | | | | | | |
| b) | Present | 25 | 96 | 24 | 120 | 100 | 5 |
| | invention | | | | | | |
| | type | | | | | | |
| c) | Present | 25 | 36 | 24 | 60 | 100 | 10 |
| | invention | | | | | | |
| | type | | | | | | |
| d) | Present | 25 | 11 | 24 | 35 | 100 | 17.1 |
| | invention | | | | | | |
| | type | | | | | | |

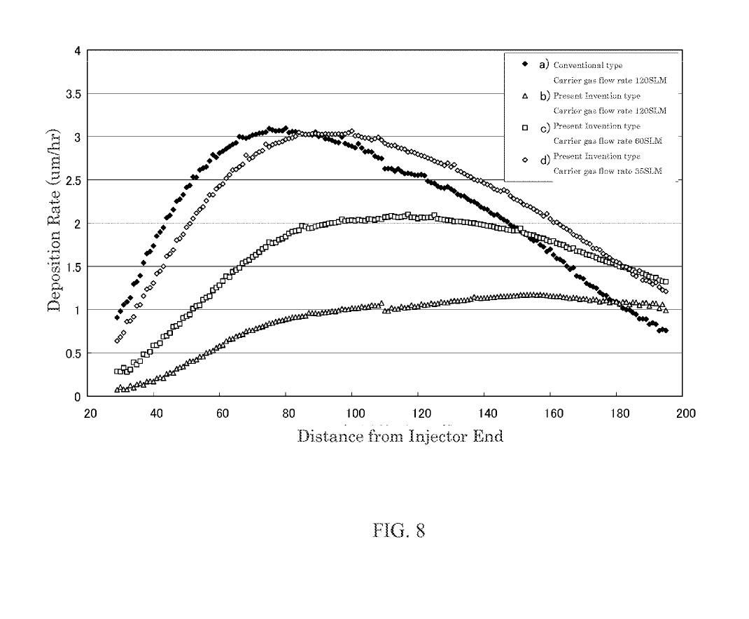

FIG. 8 shows the curves of deposition rate obtained from the results of film deposition under respective conditions. They are the results obtained on film deposition carried out at 5 rpm only by revolution but without rotation by itself. Where the structure of the present invention is used at a carrier gas flow rate of 120 SLM which is equivalent to that of the conventional structure, the curve of deposition rate extends in a lateral direction and shrinks in a longitudinal direction. This mode represents an excessively great flow velocity, which is well in line with the theory considered at the beginning of the specification. A decrease in flow rate of the carrier gas allowed the curve of deposition rate to be steep, thereby yielding a result close to that obtained by the curve of deposition rate of the conventional example at a 35 SLM flow rate of the carrier gas. In the structure of the present invention, the flow channel in a cross sectional area is about 64% of the conventional structure. Thus, it appears unusual that a similar curve of deposition rate was obtained at a flow rate of 35 SLM which was about 29% of the flow rate of the conventional structure. However, when a diffusion coefficient is taken into account, this should be a reasonable result. In the example of the present invention, the ratio of NH₃ in a carrier gas is increased. Since NH₃ has much greater in molecular weight than hydrogen, it has much smaller in diffusion coefficient than hydrogen according to Grahams' law. The curve of deposition rate is dominated by the convection diffusion equation and, therefore, will vary not only by the flow velocity but also by the diffusion coefficient. In this experimental example, it is considered that a curve of deposition rate similar to a conventional one can be obtained at a smaller flow rate of the carrier gas than expected, due to a decrease in practical diffusion coefficient of the carrier gas.

As described so far, according to the present invention, in order to obtain a curve of deposition rate similar to a conventional one, it is possible to reduce the carrier gas by 70% or more. Further, as apparent from the Table 1, the partial pressure of NH₃ is increased from conventional 5 kPa to 17.1 kPa, which is triple higher or more. Therefore, dissociation of nitrogen atoms from the surface of a film is suppressed to obtain a film in higher quality.

### Experimental Example 2

### Photoluminescence Characteristics of Multiple Quantum Well

Next, the conventional type apparatus described in Example 1 and the present invention-type apparatus were used to prepare a multiple quantum well of InGaN/GaN, thereby evaluating them by referring to photo luminescence spectra. The respective film deposition conditions are shown in the Table 2 below.

TABLE 2

| | | | Carrier gas flow | | | Flow rate of group III | | | Partial |
|---|---|---|---|---|---|---|---|---|---|
| | | Growth | rate (SLM) | | | element (sccm) | | | pressure |
| | Structure of | pressure | | | Total | TEG | TEGa | TMIn | of NH₃ |
| | apparatus | (kPa) | N₂ | NH₃ | flow rate | (barrier) | (well) | (well) | (kPa) |
| a) | Conventional | 30 | 26 | 24 | 50 | 500 | 185 | 200 | 14.4 |
| | type | | | | | | | | |
| b) | Present | 30 | 10 | 21 | 31 | 416 | 154 | 200 | 20.3 |
| | invention type | | | | | | | | |

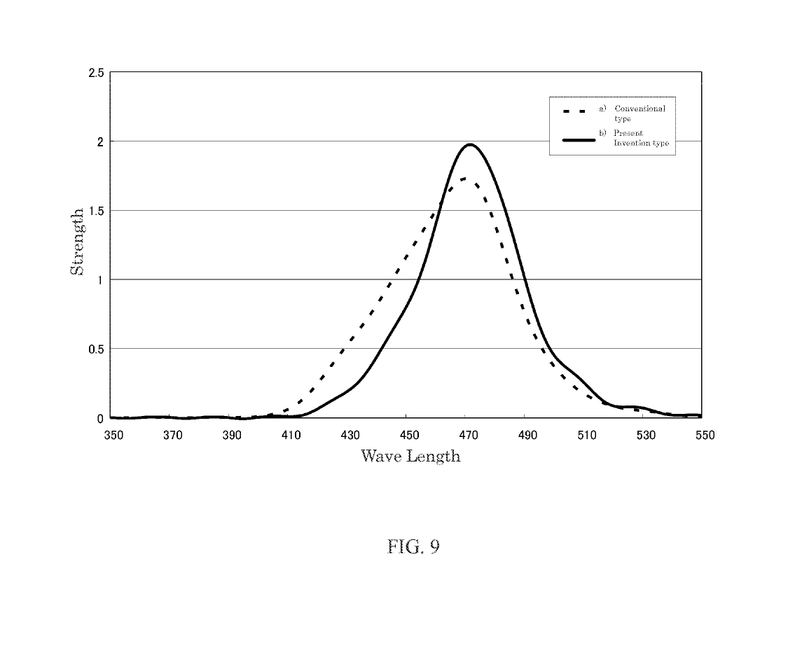

Under these film deposition conditions, a 4-inch size substrate was used to carry out film deposition by allowing the substrate to revolve at around 5 rpm and rotate by itself at 15 rpm. FIG. 9 shows photo luminescence spectra obtained by the multiple quantum well. It is apparent from this drawing that the multiple quantum well prepared by the structure of the present invention has higher peak of strength by about 15% and smaller full width at half maximum (FWHM). Of course, a film with steeper in peak and thus greater strength is in higher quality. Thus, improvement in quality of the multiple quantum well may be due to a higher partial pressure of NH₃ by about 40% as shown in the Table 2. This can be realized because the use of the structure of the present invention enables to decrease a total flow rate of the carrier gas. Further, it is possible to decrease the consumption of a group III element, in addition to consumption of gas, which provides a great contribution to a reduction in the costs of film deposition.

In addition, the present invention shall not be limited to the above-described examples but may be modified in various ways within a scope not departing from the gist of the present invention, including, for example, the following.

(1) The shape and dimensions shown in the previously described examples are one example. The present invention may be modified in design, if necessary, within its scope and provides the same effects.

(2) A material which constitutes the opposing face member 30 and the injector 40 shown in the previously described examples is one example. The present invention may be modified in design, if necessary, within its scope and provides the same effects.

(3) In the previously described examples, the injector 40 is to be used. This is, however, one example, and the injector may be installed if necessary. The structure of the injector 40 is also one example, and the present invention may be modified in design if necessary.

(4) In the previously described examples, the face-down type apparatus has the surface of the substrate facing downward. However, the present invention is also applicable to a face-up type apparatus in which the surface of the substrate faces upward.

According to the present invention, it is possible to realize the film deposition equivalent to that realized under optimal conditions by using a conventional apparatus at a smaller flow rate of the carrier gas. It is also possible to dramatically increase a partial pressure of material gases of volatile components as compared with a conventional case. This enables to form a film which is in higher quality than a conventional film. Therefore, the present invention is also applicable to a rotation/revolution type vapor phase film-deposition apparatus and in particular applicable to the film deposition of compound semiconductor films and oxide films.

### DESCRIPTION OF REFERENCE NUMERALS

10: reactor structure
20: disk-like susceptor
22: wafer holder
24: isothermal plate
26: supporting member
30: opposing face member
30A: opposing face
32: opening
34: recessed portion
34A: recessed portion opposing face
35: side wall
36: raised portion
36A: raised portion opposing face
38: gas exhaust portion
40: injector
42: first injector member
44: recessed portion
46: raised portion
48: gas introduction portion
48A: through hole
50: second injector member
52: recessed portion
54: raised portion
56: gas introduction portion
56A: through hole
60: gas introduction portion
70: opposing face member
72: opening
74: recessed portion
74A: rectangular portion
74B: fan-shaped portion
75: inclined face
76: raised portion
100: reactor structure
110: opposing face member
110A: opposing face
120: injector
122: first injector member
124: second injector member
W: substrate

1. A vapor phase film deposition apparatus: comprising a disk-like susceptor which has a wafer holder for holding a substrate for film deposition, a mechanism which allows the substrate to rotate by itself and revolve around, an opposing face which opposes the wafer holder to form a flow channel, a material gas introduction portion and an exhaust portion, and
wherein recessed and raised profiles are formed on the opposing face so that a distance between the disk-like susceptor and the opposing face is changed in a direction at which the substrate revolves around.

2. The vapor phase film-deposition apparatus according to claim 1, wherein a disk-like injector is provided at the gas introduction portion, and recessed and raised profiles are formed on the injector so as to continue to the recessed and raised profiles formed on the opposing face.

3. The vapor phase film-deposition apparatus according to claim 1, wherein a method for film deposition is based on chemical vapor growth.

4. The vapor phase film-deposition apparatus according to claim 2, wherein a method for film deposition is based on chemical vapor growth.

5. The vapor phase film-deposition apparatus according to claim 1, wherein a film to be formed is a compound semiconductor and oxidation film.

6. The vapor phase film-deposition apparatus according to claim 1, wherein part of the material gas contains an organic metal.

7. The vapor phase film-deposition apparatus according to claim 5, wherein part of the material gas contains an organic metal.

8. The vapor phase film-deposition apparatus according to claim 1, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

9. The vapor phase film-deposition apparatus according to claim 5, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

10. The vapor phase film-deposition apparatus according to claim 6, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

11. The vapor phase film-deposition apparatus according to claim 7, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

12. The vapor phase film-deposition apparatus according to claim 2, wherein a film to be formed is a compound semiconductor and oxidation film.

13. The vapor phase film-deposition apparatus according to claim 3, wherein a film to be formed is a compound semiconductor and oxidation film.

14. The vapor phase film-deposition apparatus according to claim 4, wherein a film to be formed is a compound semiconductor and oxidation film.

15. The vapor phase film-deposition apparatus according to claim 2, wherein part of the material gas contains an organic metal.

16. The vapor phase film-deposition apparatus according to claim 3, wherein part of the material gas contains an organic metal.

17. The vapor phase film-deposition apparatus according to claim 4, wherein part of the material gas contains an organic metal.

18. The vapor phase film-deposition apparatus according to claim 6, wherein part of the material gas contains an organic metal.

19. The vapor phase film-deposition apparatus according to claim 7, wherein part of the material gas contains an organic metal.

20. The vapor phase film-deposition apparatus according to claim 8, wherein part of the material gas contains an organic metal.

21. The vapor phase film-deposition apparatus according to claim 2, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

22. The vapor phase film-deposition apparatus according to claim 3, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

23. The vapor phase film-deposition apparatus according to claim 4, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

24. The vapor phase film-deposition apparatus according to claim 6, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

25. The vapor phase film-deposition apparatus according to claim 7, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

26. The vapor phase film-deposition apparatus according to claim 8, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

27. The vapor phase film-deposition apparatus according to claim 10, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

28. The vapor phase film-deposition apparatus according to claim 11, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

29. The vapor phase film-deposition apparatus according to claim 12, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

30. The vapor phase film-deposition apparatus according to claim 14, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

31. The vapor phase film-deposition apparatus according to claim 15, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.

32. The vapor phase film-deposition apparatus according to claim 16, wherein a member which constitutes the opposing face and the injector is made of any one of metal material, such as stainless steel, molybdenum; carbide such as carbon, silicon carbide and tantalum carbide; nitride such as boron nitride and aluminum nitride; and oxide-based ceramic such as quartz, alumina or in combination thereof.
